(19) United States
(12) Patent Application Publication
(10) Pub. No.: US 2025/0273510 A1
(43) Pub. Date: Aug. 28, 2025

(54) METHOD OF FORMING SEMICONDUCTOR DEVICE HAVING AIR GAP

(71) Applicant: SK hynix Inc., Icheon-si Gyeonggi-do (KR)

(72) Inventors: Jae Suk CHOI, Icheon-si Gyeonggi-do (KR); Beom Young KIM, Icheon-si Gyeonggi-do (KR); Kyung Sun RYU, Icheon-si Gyeonggi-do (KR)

(73) Assignee: SK hynix Inc., Icheon-si Gyeonggi-do (KR)

(21) Appl. No.: 19/063,858

(22) Filed: Feb. 26, 2025

(30) Foreign Application Priority Data
Feb. 27, 2024 (KR) 10-2024-0027980

(51) Int. Cl. H01L 21/768; H01L 23/532

(52) U.S. Cl. CPC H01L 21/7682; H01L 21/76829; H01L 23/5329

(57) ABSTRACT

A method of forming a semiconductor device includes forming a plurality of first conductive patterns on a substrate. A block copolymer layer is formed between the plurality of first conductive patterns. A plurality of preliminary spacers and a by-product pattern are formed from the block copolymer layer. By removing the by-product pattern, an air gap is formed. By converting the plurality of spare spacers, a plurality of spacers is formed. A capping layer is formed covering the plurality of spacers and the air gap.

### CROSS-REFERENCES TO RELATED APPLICATION

The present application claims priority under 35 U.S.C. § 119 (a) to Korean patent application number 10-2024-0027980 filed in the Korean Intellectual Property Office on Feb. 27, 2024, which application is incorporated herein by reference in its entirety.

### TECHNICAL FIELD

The disclosure relates to a method of forming a semiconductor device and a semiconductor device.

### BACKGROUND

As semiconductor devices become highly integrated, the size and spacing of conductive lines are gradually decreasing. Reducing the spacing between lines causes signal delays, such as RC delay, and various problems, such as increased leakage current. Methods for increasing insulation between lines face various technical limitations.

### SUMMARY

A method of forming a semiconductor device according to an embodiment of the disclosure may comprise forming a plurality of first conductive patterns on a substrate. A block copolymer layer may be formed between the plurality of first conductive patterns. A plurality of preliminary spacers and a by-product pattern may be formed from the block copolymer layer. By removing the by-product pattern, an air gap may be formed. By converting the plurality of spare spacers, a plurality of spacers may be formed. A capping layer may be formed covering the plurality of spacers and the air gap.

A semiconductor device according to an embodiment of the disclosure may comprise a plurality of first conductive patterns on a substrate. A plurality of spacers and an air gap may be between the plurality of first conductive patterns. The air gap may be disposed between the plurality of spacers. First surfaces of the plurality of spacers may be disposed at a level closer to the substrate than second surfaces of the plurality of first conductive patterns. A capping layer may cover the plurality of spacers and the air gap.

A semiconductor device according to an embodiment of the disclosure may comprise a first conductive pattern and a second conductive pattern on a substrate, wherein a first end of the first conductive pattern is disposed away from the substrate and a second end of the second conductive pattern is disposed away from the substrate; a first spacer adjacent to the first conductive pattern; a second spacer adjacent to the second conductive pattern, the first spacer spaced apart from the second spacer by an air gap; and a capping layer covering a first end of first spacer, a second end of the second spacer, and the air gap. The first end of the first spacer and the second end of the second spacer are closer to the substrate than the first end of the first conductive pattern and the second end of the second conductive pattern.

### BRIEF DESCRIPTION OF THE DRAWINGS

FIG. 1 is a flowchart illustrating a method of forming a semiconductor device according to embodiments of the disclosure; and

FIG. 2 to FIG. 17 are cross-sectional views of a semiconductor device formed utilizing a method according to an embodiment of the disclosure.

### DETAIL DESCRIPTION OF THE EXEMPLARY EMBODIMENTS

According to the present disclosure, a plurality of spacers and an

air gap are formed by a self-assembly method of a block copolymer layer between a plurality of first conductive patterns. A capping layer may be formed on the plurality of spacers and over or adjacent to the air gap. The air gap may increase the insulating properties between the plurality of first conductive patterns. Semiconductor devices with increased insulation between lines and are advantageous for high integration density.

Embodiments of the disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

Terms such as “vertical,” “horizontal,” “under,” “over,” “on,” “side,” “upper,” “lower,” “lowermost,” “upward,” “downward,” “high,” “low,” “level,” and other terms implying relative spatial relationship or orientation are utilized only for the purpose of ease of description or reference to a drawing and are not otherwise limiting.

When a component is designated with a value or corresponding information, such as a level, the value or the corresponding information may include a tolerance arising due to various factors, such as process factors, internal or external impact, noise, and other factors.

The cross-hatching throughout the figures illustrates corresponding or similar areas between the figures rather than indicating the materials associated with the areas.

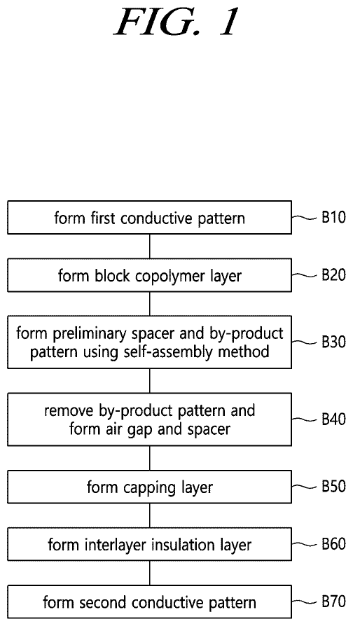

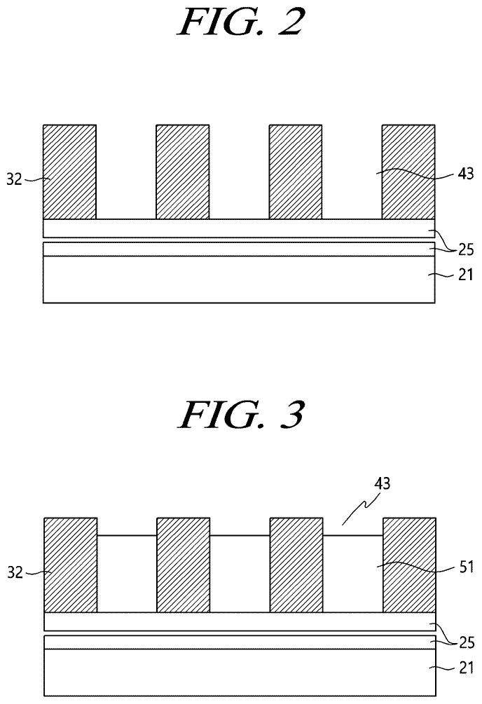

FIG. 1 is a flowchart illustrating a method of forming a semiconductor device according to embodiments of the disclosure. FIG. 2 to FIG. 9 are cross-sectional views of a semiconductor device formed utilizing a method of forming a semiconductor device according to an embodiment of the disclosure.

Referring to FIG. 1, a method of forming a semiconductor device according to an embodiment of the disclosure includes forming B10 a first conductive pattern, forming B20 a block copolymer layer, forming B30 a preliminary spacer and a by-product pattern using a self-assembly method, forming B40 an air gap and a spacer by removing the by-product pattern, forming B50 a capping layer, forming B60 an interlayer insulation layer, and forming B70 a second conductive pattern.

Referring to FIG. 1 and FIG. 2, a plurality of first conductive patterns 32 are formed B10 on a substrate 21. In an embodiment, the plurality of first conductive patterns 32 are formed on a lower insulation layer 25 covering the substrate 21. A plurality of first gap areas 43 are formed between the plurality of first conductive patterns 32.

The substrate 21 includes a semiconductor substrate such as a silicon wafer or a silicon on insulator (SOI) wafer. The substrate 21 may include a group III-V semiconductor substrate, for example, a compound semiconductor substrate such as GaAs. The substrate 21 may include monocrystalline silicon, polysilicon, amorphous silicon, monocrystalline silicon germanium, polycrystalline silicon germanium, carbon-doped silicon, or a combination thereof.

The lower insulation layer 25 includes a single layer or multiple layers. The lower insulation layer 25 may include silicon oxide, silicon nitride, silicon oxynitride, low-K dielectrics, high-K dielectrics, or a combination thereof. Internal circuits (not shown) including various active/passive elements and electrically connected to the plurality of first conductive pattern 32 may be disposed in the lower insulation layer 25 on the substrate 21.

Each of the plurality of first conductive patterns 32 includes a single layer or multiple layers. The plurality of first conductive patterns 32 includes a conductive material such as metal, metal oxide, metal nitride, metal silicide, polysilicon, conductive carbon, or a combination thereof. The plurality of first conductive patterns 32 may include W, WN, AI, Ti, TIN, Ta, TaN, Sn, Cu, Ni, Co, Mn, Mg, Ru, Zr, Pt, Ag, Au, or a combination thereof.

Each of the plurality of first conductive patterns 32 may have a different horizontal width, where horizontal is a direction relative to the drawings in FIG. 2 through FIG. 17. Each of the plurality of first gap areas 43 may have a different horizontal width.

Referring to FIG. 1 and FIG. 3, a block copolymer layer 51 is formed B20 in the plurality of first gap areas 43 between the plurality of first conductive patterns 32. Forming the block copolymer layer 51 may include utilizing a spin coating process. An upper surface of different block copolymer layers 51 may be formed at different heights. In an embodiment, the upper surface of the block copolymer layer 51 is formed at a lower level vertically with respect to the drawing than the upper surfaces of the plurality of first conductive patterns 32. For example, the upper surface or first surface of the block copolymer layer 51 is formed closer to the substrate 21 than the upper surface or second surface of the first conductive pattern 32. Thus, the second surface of the first conductive pattern 32 is farther from the substrate 21 than the first surface of the block copolymer layer 51.

The block copolymer layer 51 may include a silicon (Si)-containing block copolymer. The block copolymer layer 51 may include P2VP-b-PDMS{poly(2-vinylpyridine)-b-polydimethylsiloxane}, P4VP-b-PDMS{poly(4-vinylpyridine)-b-PDMS}, PS-b-PDMS(polystyrene-b-PDMS), PMMA-b-PDMS(polymethyl methacrylate-b-PDMS), PI-b-PDMS(polyimide-b-PDMS), or a combination thereof. In an embodiment, the block copolymer layer 51 may include P2VP-b-PDMS.

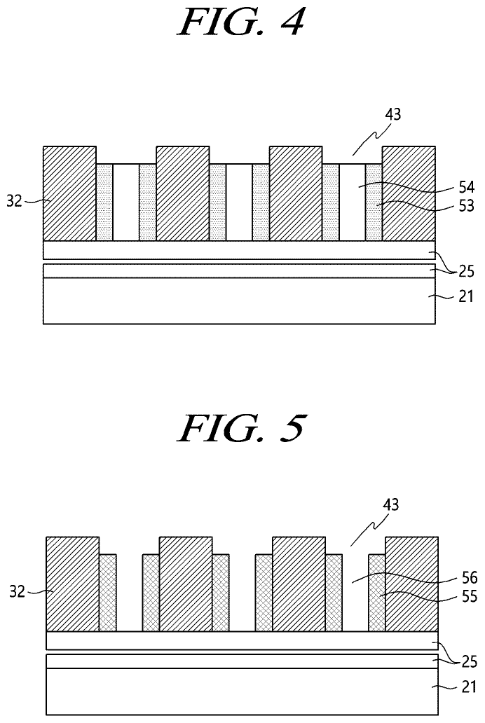

Referring to FIG. 1 and FIG. 4, a plurality of preliminary spacers 53 and a plurality of by-product patterns 54 are formed B30 from the block copolymer layer 51, for example, using a self-assembly method.

In an embodiment, forming the plurality of preliminary spacers 53 and the plurality of by-product patterns 54 using the self-assembly method may include a low-temperature heat treatment process performed in a temperature range of 50° C. to 100° C. The plurality of preliminary spacers 53 may include polydimethylsiloxane (PDMS) formed by self-assembly of P2VP-b-PDMS. The PDMS may include Si-O-CH3. The plurality of by-product patterns 54 may include P2VP{poly(2-vinylpyridine)} formed by self-assembly of P2VP-b-PDMS.

Two of the plurality of preliminary spacers 53 and a different one of the plurality of by-product patterns 54 are formed within each of the plurality of first gap areas 43. In an embodiment, each of the plurality of preliminary spacers 53 contacts an adjacent sidewall among the sidewalls of the plurality of first conductive patterns 32. Upper surfaces of the plurality of preliminary spacers 53 are formed at a lower level than upper surfaces of the plurality of first conductive patterns 32 relative to the substrate 21 in this example. A different one of the plurality of by-product patterns 54 is formed between two of the plurality of preliminary spacers 53 within each of the plurality of first gap areas 43. For example, a pair of preliminary spacers 53 and a by-product pattern 54 between the pair of preliminary spacers 53 are formed in each of the plurality of first gap areas 43.

Referring to FIG. 1 and FIG. 5, a plurality of air gaps 56 are formed by removing B40 the plurality of by-product patterns 54, and a plurality of spacers 55 are formed by converting the plurality of preliminary spacers 53.

Removing the plurality of by-product patterns 54 may include a plasma process using NH3, N2, O2, or a combination thereof. Forming the plurality of spacers 55 by converting the plurality of preliminary spacers 53 may be performed simultaneously or sequentially in the same processing chamber with forming the plurality of air gaps 56 by removing the plurality of by-product patterns 54. Transforming the plurality of preliminary spacers 53 to form the plurality of spacers 55 may include a plasma process using NH3, N2, O2, or a combination thereof. The plurality of spacers 55 may include SiN, SiO2, SiOC, SiON, SiOCN, or a combination thereof.

In an embodiment, when the plurality of preliminary spacers 53 include PDMS, Si—O—H3 included in the PDMS reacts with NH3 plasma, N2 plasma, or a combination thereof to form SiN, SiON, SiOCN, or a combination thereof, and Si—O—CH3 included in the PDMS reacts with O2 plasma to form SiO2, SiOC, or a combination thereof.

Two of the plurality of spacers 55 and a different one of the plurality of air gaps 56 are be formed within each of the plurality of first gap areas 43. In an embodiment, each of the plurality of spacers 55 contacts an adjacent sidewall of the sidewalls of the plurality of first conductive patterns 32. Upper surfaces of the plurality of spacers 55 are formed at a lower level than upper surfaces of the plurality of first conductive patterns 32 relative to the substrate 21 in this example. A different one of the plurality of air gaps 56 is formed between two of the plurality of spacers 55. For example, a pair of spacers 55 and an air gap 56 between the pair of spacers 55 are formed in each of the plurality of first gap areas 43.

Referring to FIG. 1 and FIG. 6, a capping layer 63 is formed B50 on the plurality of first conductive patterns 32 and the plurality of spacers 55 and over or adjacent to the plurality of air gaps 56. The capping layer 63 may include an insulating material such as SiN, SiBN, SiCO, or a combination thereof.

The capping layer 63 covers the plurality of spacers 55 and the plurality of air gaps 56 between the plurality of first conductive patterns 32 and covers the upper surfaces of the plurality of first conductive patterns 32. A lowermost end or surface of the capping layer 63 is formed at a lower level than the upper surfaces of a plurality of first conductive patterns 32 relative to the substrate 21. The capping layer 63 contacts side surfaces of the plurality of first conductive patterns 32 and upper surfaces of the plurality of spacers 55. In an embodiment, the capping layer 63 partially extends into the plurality of air gaps 56 between the plurality of spacers 55. The capping layer 63 partially contacts the side surfaces of the plurality of spacers 55. The plurality of air gaps 56 are preserved under the capping layer 63.

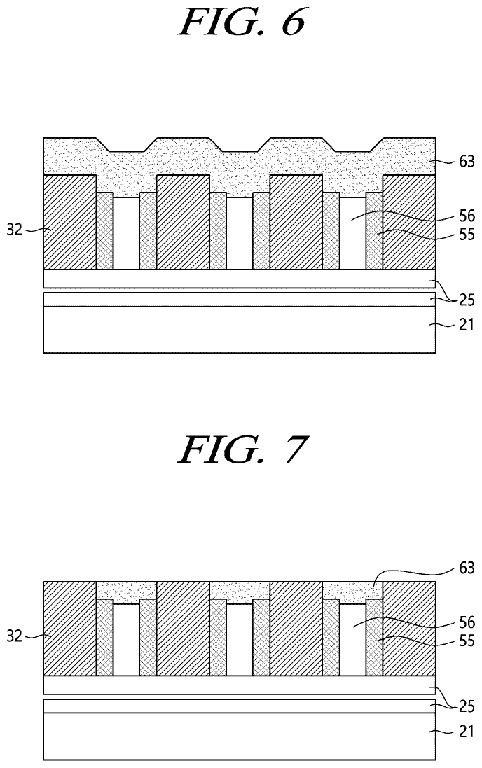

Referring to FIG. 1 and FIG. 7, in an embodiment, a planarization process is performed on the capping layer 63 while preserving the plurality of first gap areas 43 between the plurality of first conductive patterns 32 using a planarization process. The planarization process may include a chemical mechanical polishing (CMP) process, an etch-back process, or a combination thereof. Upper surfaces of the capping layer 63 and the plurality of first conductive patterns 32 are exposed in substantially the same plane. The capping layer 63 covers the plurality of spacers 55 and the plurality of air gaps 56.

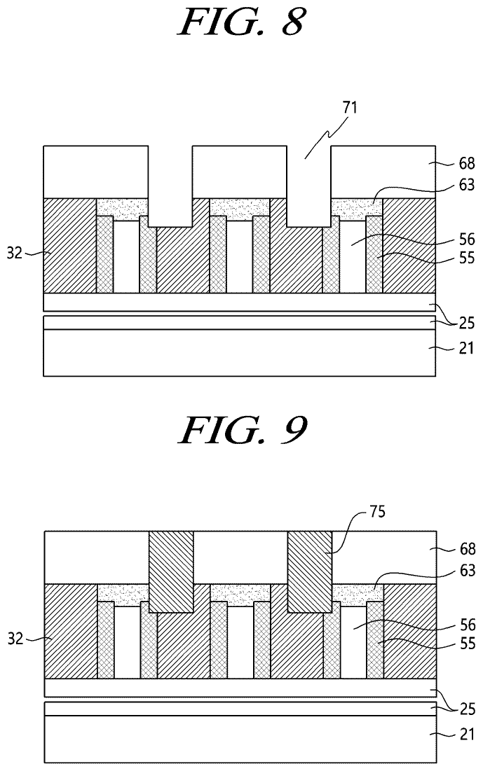

Referring to FIG. 1 and FIG. 8, an interlayer insulation layer 68 is formed B60 on the capping layer 63 and the plurality of first conductive patterns 32. A plurality of openings 71 extending through the interlayer insulation layer 68 are formed, through which openings 71 the plurality of first conductive patterns 32 are exposed. Forming the plurality of openings 71 may include an over-etching process. The plurality of openings 71 extend downwardly into the first conductive patterns 32.

A center of an opening 71 is offset from a center of a nearest first conductive pattern 32 among the plurality of first conductive patterns 32, for example, in a horizontal direction with respect to the drawings. Thus, the center of the opening 71 is not aligned with the center of the nearest first conductive pattern 32. For example, the centers of the opening 71 and the first conductive patterns 32 are centers in a horizontal direction with respect to the drawings. While forming the plurality of openings 71, the capping layer 63 and the plurality of spacers 55 are partially removed. The plurality of first conductive patterns 32, the capping layer 63, and the plurality of spacers 55 are exposed through the plurality of openings 71.

Referring to FIG. 1 and FIG. 9, a plurality of second conductive patterns 75 is formed B70 in the plurality of openings 71. The plurality of second conductive patterns 75 extends through the interlayer insulation layer 68 to contact the plurality of first conductive patterns 32.

Each of the plurality of second conductive patterns 75 includes a single layer or multiple layers. The plurality of second conductive patterns 75 may include a conductive material such as a metal, a metal oxide, metal nitride, metal silicide, polysilicon, conductive carbon, or a combination thereof.

The plurality of second conductive patterns 75 may include W, WN, Al, Ti, TiN, Ta, TaN, Sn, Cu, Ni, Co, Mn, Mg, Ru, Zr, Pt, Ag, Au, or a combination thereof.

A center of a second conductive pattern 75 is offset from a center of a nearest first conductive pattern 32 among the plurality of first conductive patterns 32, for example, in a horizontal direction with respect to the drawings.

Thus, the center of the opening 71 is not aligned with the center of the nearest first conductive pattern 32. For example, the centers of the opening 71 and the first conductive patterns 32 are centers in a horizontal direction with respect to the drawings. The plurality of second conductive patterns 75 contacts the plurality of first conductive patterns 32, the capping layer 63, and the plurality of spacers 55.

In an embodiment, when the spacer 55 is not included, the opening 71 of FIG. 8 extends into the capping layer 63 and communicates with the air gap 56. The second conductive pattern 75 extends inside the air gap 56, and a bridge is generated between the second conductive pattern 75 and the adjacent first conductive pattern 32. Leakage currents of the first conductive pattern 32 and the second conductive pattern 75 may increase.

According to an embodiment of the disclosure, a block copolymer layer 51 is formed between the plurality of first conductive patterns 32. A plurality of preliminary spacers 53 and a plurality of by-product patterns 54 are formed from the block copolymer layer 51 using a self-assembly method. A plurality of air gaps 56 are formed by removing the plurality of by-product patterns 54, and a plurality of spacers 55 are formed by converting the plurality of preliminary spacers 53. Although the spacing between consecutive first conductive patterns of the plurality of first conductive patterns 32 is narrow, a plurality of air gaps 56 and a plurality of spacers 55 are formed. Insulation characteristics between the plurality of first conductive patterns 32 may be enhanced or improved.

A plurality of second conductive patterns 75 are formed on the

plurality of first conductive patterns 32. Due to the plurality of spacers 55, the alignment margin between consecutive second conductive patterns of the plurality of second conductive patterns 75 increases. Leakage currents of the plurality of first conductive patterns 32 and the plurality of second conductive patterns 75 may be reduced. Parasitic capacitance of the plurality of first conductive patterns 32 and the plurality of second conductive patterns 75 may be reduced. The signal transfer speed of the plurality of first conductive patterns 32 and the plurality of second conductive patterns 75 may increase.

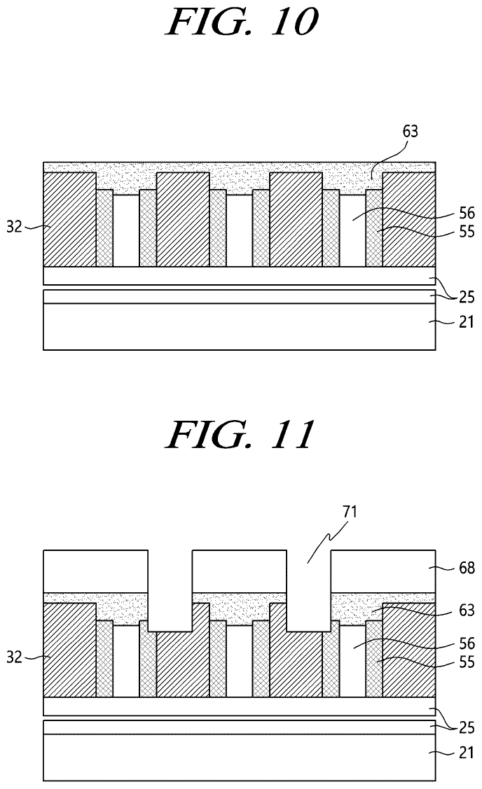

FIG. 10 to FIG. 12 are cross-sectional views of a semiconductor device formed utilizing a method of forming a semiconductor device according to an embodiment of the disclosure.

Referring to FIG. 10, the capping layer 63 includes a planarized upper surface. The capping layer 63 covers the plurality of first conductive patterns 32, the plurality of spacers 55, and the plurality of air gaps 56.

Referring to FIG. 11, an interlayer insulation layer 68 is formed on the capping layer 63. A plurality of openings 71 extending through the interlayer insulation layer 68 and the capping layer 63 are formed, through which openings 71 the plurality of first conductive patterns 32 are exposed. The plurality of first conductive patterns 32, the capping layer 63, and the plurality of spacers 55 are exposed through the plurality of openings 71.

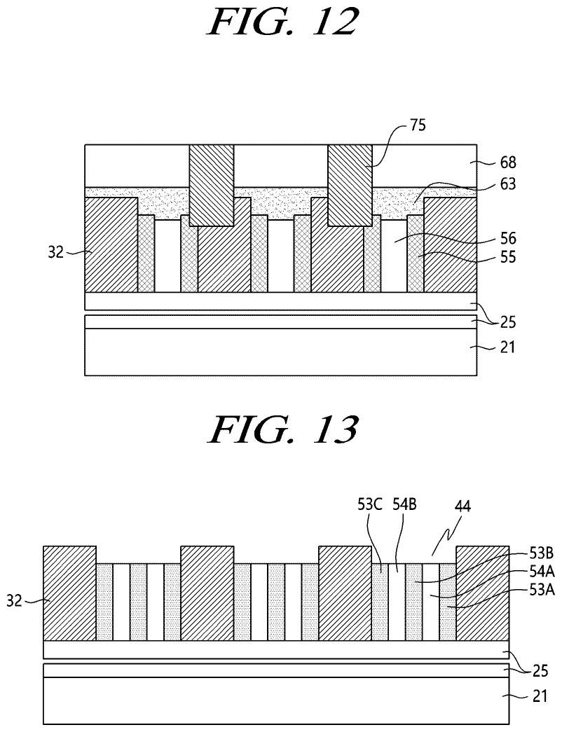

Referring to FIG. 12, a plurality of second conductive patterns 75 are formed in the plurality of openings 71. The plurality of second conductive patterns 75 extends through the interlayer insulation layer 68 and the capping layer 63 and contacts the plurality of first conductive patterns 32.

FIG. 13 to FIG. 16 are cross-sectional views of a semiconductor device formed utilizing a method of forming a semiconductor device according to an embodiment of the disclosure.

Referring to FIG. 13, a plurality of second gap areas 44 are formed between the plurality of first conductive patterns 32. The horizontal width of each of the plurality of second gap areas 44 may be larger than the horizontal width of each of the plurality of first gap areas 43 of FIG. 2. A plurality of preliminary spacers 53A, 53B, 53C and a plurality of by-product patterns 54A, 54B are formed from the block copolymer layer 51 using a self-assembly method.

In an embodiment, the plurality of preliminary spacers includes a first preliminary spacer 53A, a second preliminary spacer 53B, and a third preliminary spacer 53C. The plurality of by-product patterns includes a first by-product pattern 54A and a second by-product pattern 54B. The first preliminary spacer 53A, the second preliminary spacer 53B, and the third preliminary spacer 53C are alternately formed with the first by-product pattern 54A and the second by-product pattern 54B.

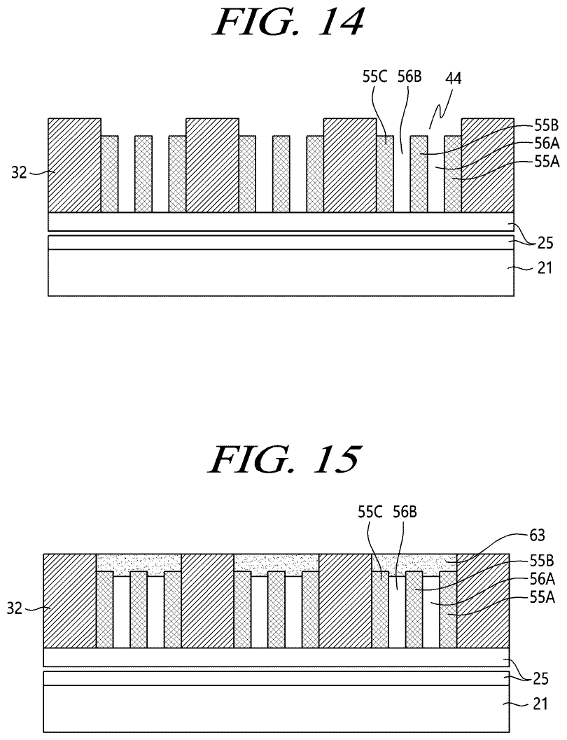

Referring to FIG. 14, a plurality of air gaps 56A, 56B are formed by removing the plurality of by-product patterns 54A, 54B, and a plurality of spacers 55A, 55B, 55C are formed by converting the plurality of preliminary spacers 53A, 53B, 53C. In an embodiment, the plurality of spacers includes a first spacer 55A, a second spacer 55B, and a third spacer 55C. The plurality of air gaps includes a first air gap 56A and a second air gap 56B. The first spacer 55A, the second spacer 55B, and the third spacer 55C are alternately formed with the first air gap 56A and the second air gap 56B.

Referring to FIG. 15, a capping layer 63 is formed on the plurality of spacers 55 and the plurality of air gaps 56.

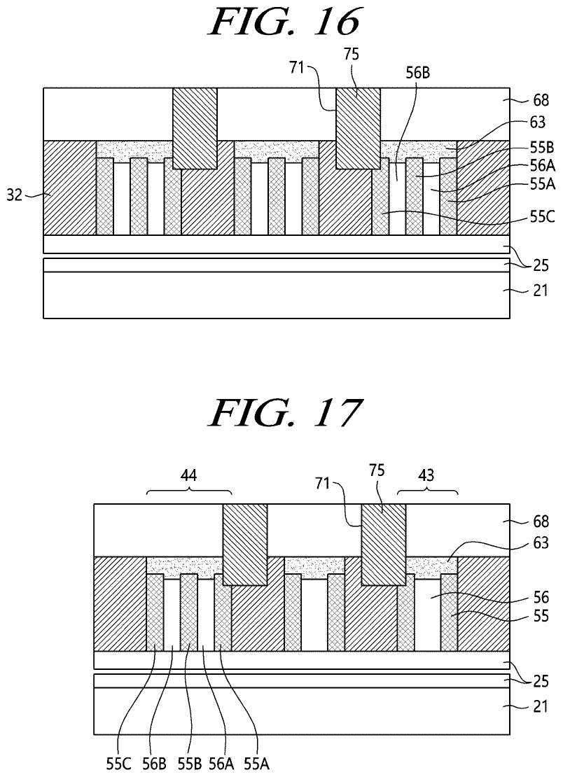

Referring to FIG. 16, an interlayer insulation layer 68 is formed on the capping layer 63 and the plurality of first conductive patterns 32. A plurality of openings 71 extending through the interlayer insulation layer 68 are formed, through which the plurality of first conductive patterns 32 are exposed. A plurality of second conductive patterns 75 are formed in the plurality of openings 71.

FIG. 17 is a cross-sectional view of a semiconductor device formed utilizing a method of forming a semiconductor device according to an embodiment of the disclosure.

Referring to FIG. 17, a plurality of first gap areas 43 and second gap areas 44 are formed between the plurality of first conductive patterns 32. The horizontal width of each of the plurality of first gap areas 43 is smaller than the horizontal width of the second gap area 44. A plurality of spacers 55, 55A, 55B, 55C and a plurality of air gaps 56, 56A, 56B are formed in the plurality of first gap areas 43 and second gap areas 44. In the second gap area 44, the first spacer 55A, the second spacer 55B, and the third spacer 55C are alternately formed with the first air gap 56A and the second air gap 56B.

A capping layer 63 is formed on the plurality of spacers 55 and over or adjacent to the plurality of air gaps 56. An interlayer insulation layer 68 is formed on the capping layer 63 and the plurality of first conductive patterns 32. A plurality of openings 71 extending through the interlayer insulation layer 68 are formed, through which the plurality of first conductive patterns 32 are exposed. A different one of the plurality of second conductive patterns 75 is formed in a corresponding one of the plurality of openings 71. Concepts are disclosed in conjunction with examples and

embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A method of forming a semiconductor device, the method comprising:
forming a plurality of first conductive patterns on a substrate;
forming a block copolymer layer between the plurality of first conductive patterns;
forming a plurality of preliminary spaces and a by-product pattern from the block copolymer layer;
forming an air gap by removing the by-product pattern;
forming a plurality of spacers by converting the plurality of preliminary spaces; and
forming a capping layer covering the plurality of spacers and the air gap.

2. The method of claim 1, wherein the block copolymer layer includes a silicon (Si)-containing block copolymer.

3. The method of claim 1, wherein the block copolymer layer includes P2VP-b-PDMS{poly(2-vinylpyridine)-b-polydimethylsiloxane}, P4VP-b-PDMS{poly(4-vinylpyridine)-b-PDMS}, PS-b-PDMS(polystyrene-b-PDMS), PMMA-b-PDMS(polymethyl methacrylate-b-PDMS), PI-b-PDMS(polyimide-b-PDMS), or a combination thereof.

4. The method of claim 1 wherein the plurality of preliminary spacers include polydimethylsiloxane (PDMS).

5. The method of claim 1, wherein the plurality of spacers include SiN, SiO2, SiOC, SiON, SiOCN, or a combination thereof.

6. The method of claim 1, wherein each of the plurality of spacers contacts an adjacent sidewall of sidewalls of the plurality of first conductive patterns, and wherein the air gap is formed between the plurality of spacers.

7. The method of claim 1, wherein surfaces of the plurality of spacers farthest from the substrate are formed at a level closer to the substrate than surfaces of the plurality of first conductive patterns farthest from the substrate.

8. The method of claim 1, wherein the capping layer contacts side surfaces of the plurality of first conductive patterns.

9. The method of claim 1, wherein the capping layer includes SiN, SiBN, SiCO, or a combination thereof.

10. The method of claim 1, wherein forming the plurality of preliminary spacers and the by-product pattern includes a low-temperature heat treatment process performed in a temperature range of 50° C. to 100° C.

11. The method of claim 1, further comprising:
forming an interlayer insulation layer on the plurality of first conductive patterns and the capping layer; and
forming a second conductive pattern extending through the interlayer insulation layer and contacting a corresponding first conductive pattern among the plurality of first conductive patterns.

12. The method of claim 11, wherein a center of the second conductive pattern is offset in a first direction from a center of a nearest first conductive pattern among the plurality of first conductive patterns.

13. A semiconductor device comprising:
a plurality of first conductive patterns on a substrate;
a plurality of spacers and an air gap between the plurality of first conductive patterns, the air gap disposed between the plurality of spacers, and first surfaces of the plurality of spacers are disposed at a level closer to the substrate than second surfaces of the plurality of first conductive patterns; and
a capping layer covering the plurality of spacers and the air gap.

14. The semiconductor device of claim 13, wherein each of the plurality of spacers contacts an adjacent one among sidewalls of the plurality of first conductive patterns.

15. The semiconductor device of claim 13, wherein a surface of the capping layer closest to the substrate is disposed at a level closer to the substrate than surfaces of the plurality of first conductive patterns farthest from the substrate.

16. The semiconductor device of claim 13, wherein the capping layer contacts side surfaces of the plurality of first conductive patterns.

17. The semiconductor device of claim 13, wherein the plurality of spacers include SiN, SiO2, SiOC, SiON, SiOCN, or a combination thereof.

18. The semiconductor device of claim 13, further comprising:
an interlayer insulation layer on the plurality of first conductive patterns and the capping layer; and
a second conductive pattern extending through the interlayer insulation layer and contacting a corresponding first conductive pattern among the plurality of first conductive patterns.

19. The semiconductor device of claim 18, wherein a center of the second conductive pattern is offset from a center of a nearest first conductive pattern among the plurality of first conductive patterns.

20. A semiconductor device comprising:
a first conductive pattern and a second conductive pattern on a substrate, wherein a first end of the first conductive pattern is disposed away from the substrate and a second end of the second conductive pattern is disposed away from the substrate;
a first spacer adjacent to the first conductive pattern;
a second spacer adjacent to the second conductive pattern, the first spacer spaced apart from the second spacer by an air gap; and
a capping layer covering a first end of first spacer, a second end of the second spacer, and the air gap;
wherein the first end of the first spacer and the second end of the second spacer are closer to the substrate than the first end of the first conductive pattern and the second end of the second conductive pattern.
